(19) United States
(12) Patent Application Publication
(10) Pub. No.: US 2008/0116468 A1
(43) Pub. Date: May 22, 2008

(54) LED backlight using discrete RGB phosphors

(75) Inventors: Emil Vergilov Radkov, Euclid, OH (US); Thomas F. Soules, Livermore, CA (US); Larry Stadelman, Stow, OH (US)

Correspondence Address: FAY SHARPE LLP, 1100 SUPERIOR AVENUE, SEVENTH FLOOR, CLEVELAND, OH, 44114, US

(73) Assignee: GELcore LLC

(21) Appl. No.: 11/603,804

(22) Filed: Nov. 22, 2006

(51) Int. Cl. H01L 33/00; G02B 26/02; G02B 5/22; F21V 1/00

(52) U.S. Cl. 257/89; 362/240; 257/E33.061

(57) ABSTRACT

An LED backlight apparatus includes a plurality of radiation emitting diodes, each diode emits radiation having a peak wavelength of about less than 430 nm. Each diode is located on a back surface of a housing. The housing may have an opening. A screen covers the opening and the screen includes a discrete pattern of phosphor coated red light emitting pixels, a second discrete pattern of phosphor coated green light emitting pixels, and a third discrete pattern of phosphor coated blue light emitting pixels. The emitted radiation may excite the phosphor coated pixels. The apparatus may also include a radiation regulating element proximate the screen and further include a diffuser proximate the diodes.

### BACKGROUND

The present exemplary embodiment relates to backlighting. It finds particular application in conjunction with diode backlighting, and will be described with particular reference thereto. However, it is to be appreciated that the present exemplary embodiment is also amenable to other like applications.

Backlight products currently available in the market place today, typically utilize cold cathode fluorescent lamp (“CCFL”) technology to backlight the product, and edge lighting with white CCFLs is commonly used in liquid crystal displays (“LCDs”). CCFL technology is an inexpensive way to backlight a product. However, CCFL technology is limited in terms of its power output. Also CCFL technology is not the most energy efficient lighting technique. Additionally, CCFL technology has spacing requirements that are inconsistent with current trends of making products thinner and smaller in response to the desires of today's consumers.

Another type of backlighting technology is the use of light emitting diodes (“LEDs”). In one embodiment used in current LCDs, LEDs emitting white light require that the light be separated into red, green, and blue components by filtering. The white light may be phosphor converted LEDs or pre-mixed from red, green, and blue LED chips. The filtering introduces light losses due to at least the reason that the filter eliminates light of wavelengths other than the desired wavelengths for pixel emission. This results in a reduction in the brightness of the screen and may also reduce the gamut, due to insufficient rejection of undesired wavelengths. Further after passing from the white light source, the light has a directionality so that when the screen is viewed at angles other than the optimal angle, the intensity of the light decreases and the colors of the light often shift.

### BRIEF DESCRIPTION

A radiation emitting diode backlight apparatus is described herein. The apparatus may include a plurality of radiation emitting diodes, each diode emits radiation having a peak wavelength of about less than 430 nm. Each diode is located on a back surface of a housing. The housing may have an opening. A screen covers the opening and the screen includes a discrete pattern of phosphor coated red light emitting pixels, a second discrete pattern of phosphor coated green light emitting pixels, and a third discrete pattern of phosphor coated blue light emitting pixels. A radiation regulating element may be located proximate to the screen and a diffuser may be located proximate to the diodes.

### BRIEF DESCRIPTION OF THE DRAWINGS

FIG. 1 is an exploded view an embodiment of an apparatus in accordance with the backlight apparatus disclosed herein.

FIG. 2A is a front view of an additional embodiment of such an apparatus.

FIG. 2B is a side view of the additional embodiment of the apparatus.

FIG. 3A is a front view of another embodiment of such an apparatus.

FIG. 3B is a side view of the another embodiment shown in FIG. 3A.

FIG. 4 is an exploded view of a further embodiment of an apparatus disclosed herein.

FIG. 5 depicts the spectral power distribution for a backlight example.

### DETAILED DESCRIPTION

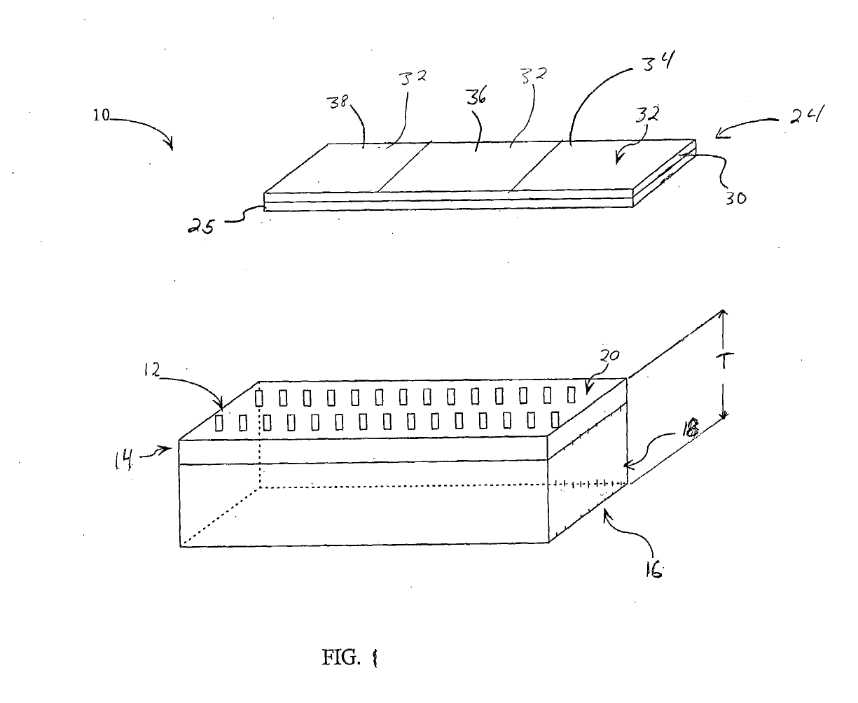

With reference to FIG. 1, depicted is a backlit apparatus 10. Apparatus 10 includes a plurality of radiation emitting diodes 12. Preferably each diode emits radiation having a peak wavelength of about less than 430 nm. In one embodiment, the peak wavelength is less than 420 nm. In another embodiment, the peak wavelength is about 390 nm to about 420 nm. In another exemplary embodiment the peak wavelength is about 395 nm to about 415 nm.

An example of a diode which may be used to emit the aforementioned radiation is an LED. However described apparatus 10 is not limited to only the use of LEDs as diode 12, the apparatus 10 will be further described herein in terms of LEDs for easy of illustration. In one particular embodiment, diodes 12 may include anyone of the following types of LEDs such as violet emitting LEDs or near-UV emitting LEDs. In a further embodiment, LEDs 12 may be power LEDs. Preferably, the operating current of a power LED is at least 300 mA, more preferably at least about 500 mA, and even more preferably at least about 700 mA. Use of power LEDs may enable a backlight manufacturer to reduce the number of LEDs required for a certain application by a factor of about 10. Preferably LEDs 12 are located within a housing 14. In one embodiment, one of more of LEDs 12 is located on a back surface 16 of housing 14.

In a particular embodiment, preferably LEDs 12 are uniformly spaced apart. Preferably, LEDs 12 are spaced apart to provide apparatus 10 with a sufficiently uniform radiometric flux. In another particular embodiment, LEDs 12 are not aligned as side lights or as edge lights. In another preferred embodiment a suitable light diffuser is placed between the LED's and the screen to further enhance the uniformity of the radiometric flux from the LEDs. Examples of suitable diffusers are but are not limited to glass or plastic sheets with etched or molded refractive elements or a holographic interference pattern. In still another embodiment the diffuser may comprise a sheet designed with refractors on at least one surface, wherein the LEDs may be oriented to the sheet so as to illuminate a edge or side thereof.

Housing 14 may have one or more vertical surfaces 18. Housing 14 is depicted as having a rectangular orientation; however, the invention is applicable to housing 14 having any particular shape, size, or configuration. Housing 14 also may have an open top 20. In an embodiment housing 14 has a thickness (“T”) of less than about seven (7″) inches, preferably less than about five (5″) inches, and even more preferably less than about four (4″) inches. In one particular embodiment, housing 14 may be about two (2) or less inches thick and in another embodiment, housing 14 may be about one (1) inch or less thick.

Apparatus 10 may also include a screen 24. Preferably screen 24 includes a plurality of pixels in region 30 of screen 24. Optionally, the pixels may be encapsulated. Silicone is one example of a suitable encapsulant. Preferably, the pixels may be coated with phosphor material 32. In one embodiment, the pixels are coated with phosphor 32 in such a manner that the screen 24 includes a patterned region of discrete red emitting pixels 34, green emitting pixels 36, and blue emitting pixels 38. In one embodiment of apparatus 10, a peak wavelength of the one or more pixels of the discrete pattern of red light emitting pixels comprises between about 610 nm to about 660 nm, preferably a peak wavelength about 620 nm to about 640 nm, a peak wavelength of the one or more pixels of the discrete pattern of green light emitting pixels comprises between about 500 nm to about 560 nm, preferably a peak wavelength of about 510 nm to about 540 nm, and a peak wavelength of the one or more pixels of the discrete pattern of blue light emitting pixels comprises between about 440 nm to about 470 nm, preferably a peak wavelength of about 445 nm to about 465 nm. In a further preferred embodiment of apparatus 10, screen 24 will not emit light having a peak wavelength of about 480 nm to about 500 nm and/or of 580 nm to about 600 nm. In one embodiment, diodes 12 may supply the radiation to excite a particular pixel to emit a desired light of the appropriate wavelength as described above.

One or more of the phosphor coated pixels may include a pigment. Preferably, the pigment included on a particular pixel is of the same color as that of the light emitted by the pixel. For example, if the pixel emits light having a peak wavelength within the region of blue light, the pigment that coats the pixel absorbs light outside the blue region and transmits light inside said region. In other words, the pigment preferably will transmit light generated from the phosphor of the desired wavelengths of light, this may be known as the “pixel emissions range” for a particular pigment. A person of ordinary skill in the art will realize that the pixel emission range for a particular range of wavelengths may be somewhat broader than the aforementioned above wavelengths of red, green, and blue emitted light from the pixels. One advantage of including the pigment in phosphor 32 is that it will eliminate “cross-talk” between pixels of different colors. A second advantage of including the pigment is that it will suppress emitting light of the non-chosen range of wavelengths. For example in the case of a phosphor coated pixel designed to emit light in the blue region, the use of pigment in the phosphor will suppress the emission of light outside the wavelengths of about 440 nm to about 470 nm. The method for coating phosphors and phosphors plus pigments by optical lithography is common in the art and is the same as used for coating cathode ray screens (CRTs) commonly used in CRT colored televisions.

Various types of phosphor material which will absorb the violet or near UV light of the LEDs and convert it to visible light at saturated RGB (red, green, and blue) colors that may be used to coat screen 24. Suitable types of phosphors for the generation of red light include oxysulfides doped with Eu³⁺ (e.g. La₂O₂S: Eu³⁺), oxyfluorides doped with Mn⁴⁺ (e.g. 3.5MgO*0.5MgF2*GeO₂: Mn⁴⁺ ), complex fluorides doped with Mn⁴⁺ (e.g. K₂[TiF₆]: Mn⁴⁺) and nitridosilicates doped with Eu²⁺ (e.g. CaAlSiN₃: Eu²⁺). Suitable types of phosphors for the generation of green light include thiogallates doped with Eu²⁺ (e.g. SrGa₂S₄: Eu²⁺), silicates doped with Eu²⁺ (e.g. Ba₂SiO₄: Eu²⁺), sulfides doped with Cu⁺ (e.g. ZnS: Cu⁺), aluminates doped with Eu²⁺ (e.g. SrAl₂O₄: Eu²⁺) and BaMgAl₁₀O₁₇: Eu²⁺, Mn²⁺. Suitable types of phosphor for the generation of blue light include halophosphates doped with Eu²⁺ (e. g. Sr₅(PO₄)₃Cl: Eu²⁺), sulfides doped with Ag⁺ (e.g. ZnS: Ag⁺), and BaMgAl₁₀O₁₇: Eu²⁺. It will be clear to one skilled in the art that other phosphors having similar excitation and emission characteristics may be used instead of the preceding types.

As for the relationship between LEDs 12 and screen 24, LEDs 12 may be spaced any desired distance away from screen 24. In one embodiment, it is preferred that LEDs 12 are spaced a distance “D” away from screen 24 such that the apparatus 10 exhibits a uniform illumination. In an embodiment, distance “D” may comprise less than the spacing between adjacent LEDs. In a further embodiment, the distance “D” may be described in terms of a relationship between the distance “D” and the pitch (P) of LEDs 12. Pitch is the distance between centerline to centerline of adjacent LEDs 12. In this embodiment, the distance “D” may be between about 0.3 times to less than about 1.2 times the pitch of the LEDs.

In another alternative embodiment, apparatus 10 includes less than one (1) LED per pixel. Furthermore, it is preferred that apparatus 10 includes less than one (1) LED per one hundred (100) pixels, more preferred less than one (1) LED per one-thousand (1,000) pixels, even more preferred less than one (1) LED per ten-thousand (10,000) pixels, and most preferred less than one (1) LED per one-hundred thousand (100,000) pixels.

One example of how screen 24 may be made is described below. Screen 24 may be formed of any suitable polymeric or glass substrate. In one embodiment, the substrate has a high transmission having a transmittance of at least 80% of light having a wavelength of 430 to 680 nm. In this embodiment, preferably the substrate is cleaned with suitable washing solution, e. g. a caustic solution. The substrate is then rinsed with water, etched with a buffered hydrofluoric acid and rinsed again with water.

A light converting matrix is applied to a surface of screen 24 which is intended to face LEDs 12. Preferably, the matrix is uniformly provided over the entire portion of the surface intended to receive light from LEDs 12. Examples of matrices are disclosed in the following U.S. patents, which are all incorporated herein by reference in their entirety, U.S. Pat. No. 3,558,310, U.S. Pat. No. 6,013,400, and U.S. Pat. No. 6,037,086.

Lastly, red, green, and blue phosphors can be applied to screen 24 to form the discrete pattern discussed above. For more information on forming screen 24 and alternate embodiments on how to form screen 24, the following patent documents are incorporated herein be reference in their entirety: US 2004/0169455, U.S. Pat. No. 5,259,877, U.S. Pat. No. 4,293,586, U.S. Pat. No. 3,965,031, EP 0234519, and WO 03/052786.

Apparatus 10 may include a diffuser 25. Preferably diffuser 25 is located proximate LEDs 12. In an embodiment, diffuser 25 is aligned perpendicular to the direction of the main optical axis of the LEDs 12 to diffuse the radiation emitted from LEDs 12, preferably diffuser 25 uniformly diffuses the radiation. In one particular embodiment, there is no component located between diffuser 25 and LEDs 12. In another embodiment, diffuser 25 is located below screen 24 and above LEDs 12. A preferred type of diffuser is a refractory diffuser. In one embodiment, diffuser 25 may include a substrate which has a transmittance of at least about 80% of the light that it receives, more preferably at least about 85%, and even more preferably at least about 90%. Preferred materials of construction of diffuser 25 include glass and/or a transparent polymeric material. Diffuser 25 may be a random diffuser, such as an etched substrate or a substrate having a random ribbed pattern or it may be a uniform diffuser, such as a diffuser having a uniform pattern. One such diffuser having the uniform pattern may be a holographic diffuser designed to spread light out over a specified range of angles in two perpendicular directions in the plane of the diffuser.

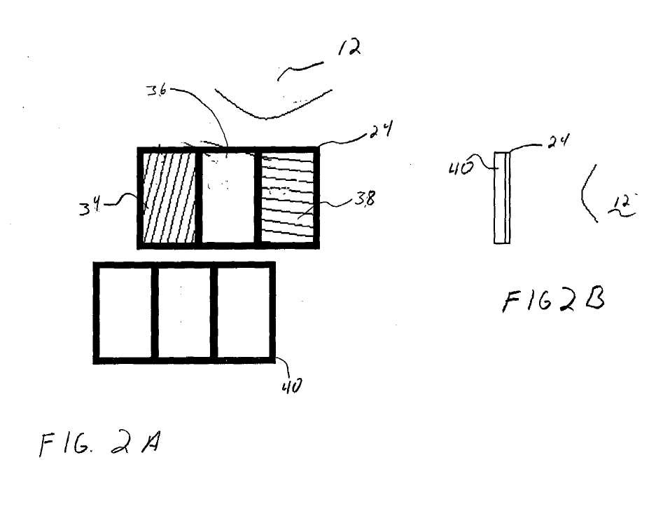

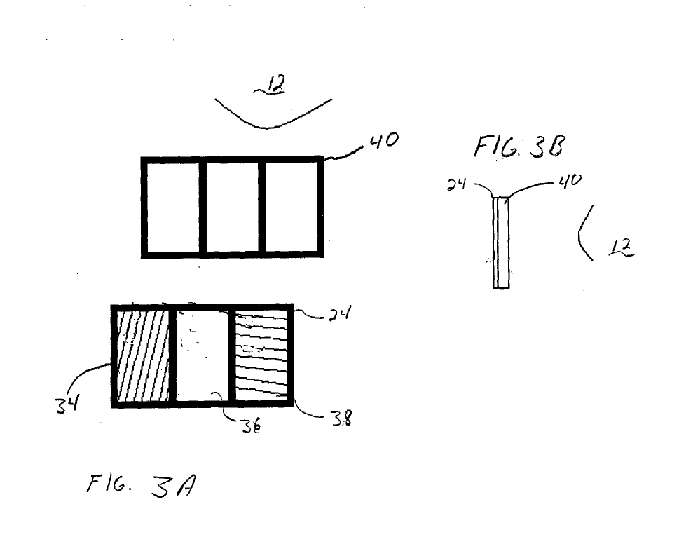

Apparatus 10 may also include a radiation regulating element. Preferably, the radiation regulating element will control the emission of radiation to screen 24. With reference to FIGS. 2A-3B an embodiment of the regulating element will be further described in terms of a shutter. As depicted apparatus 10 may further include a shutter 40. In one embodiment, shutter 40 may act to modulate the intensity of the UV radiation from the LEDs by exciting one or more of the phosphor pixels. The UV radiation may include near UV radiation, far UV radiation, or radiation of less than about 430 nm, and combinations thereof. As depicted in FIGS. 2A and 2B, shutter 40 may be located adjacent to screen 24 on an opposite side of screen 24 as LEDs 12. FIG. 2A also includes one embodiment of the discrete regions 34, 36, and 38 of red, green, and blue emitting pixels. As shown in FIGS. 2A and 3A, the discrete regions include three (3) adjacent regions of pixels which emit different color light as indicated. An alternate embodiment of apparatus 10 is illustrated in FIGS. 3A and 3B. FIG. 3B exhibits an embodiment of apparatus 10 in which shutter 40 is adjacent to screen 24 on a side of screen 24 facing LEDs 12.

In one particular embodiment, shutter 40 is a suitable size to cover each of the discrete regions 34, 36, 38 of screen 24.

In another particular embodiment, shutter 40 has an appropriate response time. One example of an appropriate response time is less than about one (1) millisecond. In a further embodiment, shutter 40 may operate on a gradual frequency in which shutter 40 is time gated and opens frequently. Another embodiment of shutter 40 may be a mechanical shutter.

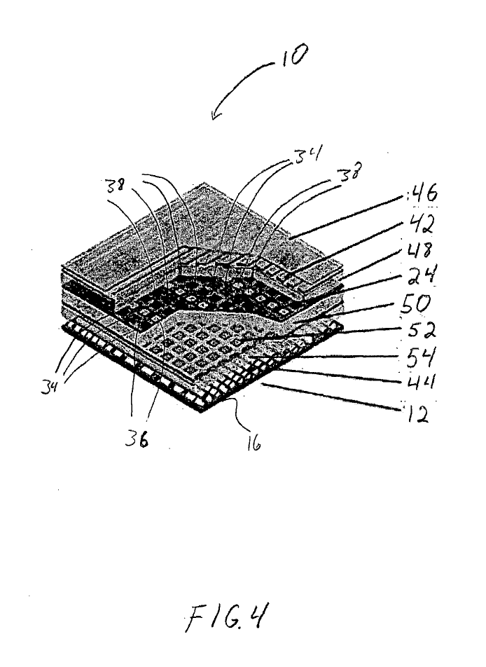

Another example of the regulating element may include one or more polarizing filters. As shown in FIG. 4, apparatus 10 may include LEDs 12 and screen 24 Preferably the filters may be located on either side of screen 24. Apparatus 10 may also optionally include polarizing filters 42 and 44. As shown polarizing filter 44 is located above screen 24 and opposite of LEDs 12. In the illustrated embodiment, filter 44 is a horizontal polarizing filter. Further illustrated, FIG. 4 includes a vertical polarizing filter 42 located between screen 24 and LEDs 12. In an alternate embodiment, the locations of filters 42 and 44 may be switched. In a further alternate embodiment, apparatus 10 may include only one of filter 44 and filter 42. The one of filters 42 and 44 may be located on either side of screen 24. Examples of suitable polarizing filters include polarizing filters, actuated or rotated by an applied voltage, such as, liquid crystal cross polarizing filters commonly used in LCDs. The current invention, however, should not be limited to the LCD method of filtering With actuated cross polarizers but may include any method whereby the radiometric flux from the LED's reaching each phosphor pixel may be regulated by a voltage. In preferred embodiments, the radiation regulating element may be located proximate screen 24. The radiation regulating element may be located on the side of screen 24 facing LEDs 12 or on the opposing side of screen 24.

A further embodiment of shutter 40 may be a microelectromechanical system (“MEMS”) device. A source of such shutters may include Vincent Associates of Rochester, N.Y. An example of one of their lines of shutter products is marketed under the UNIBLITZ® trademark. UNIBLITZ® is a registered trademark of Vincent Associates. Another source of shutter(s) may include ColorLink, Inc. of Boulder, Colo. Additional description regarding shutters may be found in U.S. Pat. No. 5,459,602 assigned to Texas Instruments and U.S. Pat. No. 6,965,477 assigned to Alps Electric Company. Both of the patents are incorporated herein by reference in their entirety. Alternatively, shutter 40 may also be a digital light processor (“DLP”). Texas Instruments is an example of one source of a DLP. A further embodiment of shutter 40 may include an electro-optical shutter.

Also illustrated in FIG. 4 is another discrete pattern of red, green, and blue light emitting pixels 34, 36, and 38. As shown, each red light emitting region is shown as particular region 34 of screen 24. Additionally each green light emitting region 36 is shown as a particular region of screen 24 and lastly each blue light emitting region 38 of screen 24 is shown as a particular region. As illustrated, each discrete region is made up of columns of individual rectangles of a particular light emitting region. In an alternate embodiment, the discrete pattern of red, green, and blue pixels may be made up of discrete red light emitting oval dots, discrete green light emitting oval dots, and discrete blue light emitting oval dots. In yet another embodiment, circular dots may be used for the discreet red, green and blue pixels.

Optionally, as shown in FIG. 4, apparatus 10 may further include any one of the following components: front plate 46, front glass plate 48, liquid crystal display 50, subpixel electrodes 52, rear glass plate 54, and combinations thereof. The various optional components of apparatus 10 illustrated in FIG. 4 may be arranged in any orientation relative to screen 24, as well as to each other. Preferably, LEDs 12 are located on a bottom surface 16 of a housing (not shown). A further alternative embodiment includes an assembly of liquid crystal display 50 sandwiched between a pair of polarizers 44, 42. The assembly is located between screen 24 and diffuser 25. Optionally, shutter 40 may be included adjacent screen 24 and the assembly.

In an alternative embodiment, apparatus 10 may include a light filter. Preferably, the filter is a UV filter. The filter may be positioned to remove light below 430 nm which may pass through screen 24. In a further alternate embodiment, screen 24 may include a mask. The mask may be located around the red, green, and blue emitting pixels. A benefit of the mask is that it will mitigate “cross-talk” between adjacent pixels. An example of materials which may be used to make the mask include metal, graphite, carbon black, and combinations thereof. However, the aforementioned list of materials is not intended to be an exhaustive list of suitable materials, other suitable materials may be used to produce the mask.

The various embodiments of apparatus 10 discussed above may be practiced in any and all combinations thereof.

An advantage of the apparatus is that it may emit omni-directional light. In one embodiment, described herein, it is believed that by virtue of having shuttered radiation filtered before striking the screen 24, the light emitted by the discrete pattern on screen 24 will radiate uniformly in all directions, much like a standard cathode ray screen (CRT) or “plasma display”. By virtue of being excited by high radiometric flux of LEDs, the apparatus will have improved brightness over other backlighting technologies such as CCFL, CRT, and plasma. Apparatuses made in accordance with the above disclosure will have all the compactness and resolution of the high-end liquid crystal displays (LCD's). Also these apparatuses will be much brighter than either LCD or plasma screens currently available.

Other advantages include that the invention may be used to produce an apparatus which exhibits at least one of appropriate brightness, color uniformity, reduced number of hot spots, reduced energy consumption, reduced thickness and combinations thereof. An apparatus made in accordance with the above also has the advantage of minimal light loss, reduced gamut reduction, and will not include bright spots. In a particular apparatus 10, if maximum brightness is required, apparatus 10 may be substantially devoid of filters and/or polarizers.

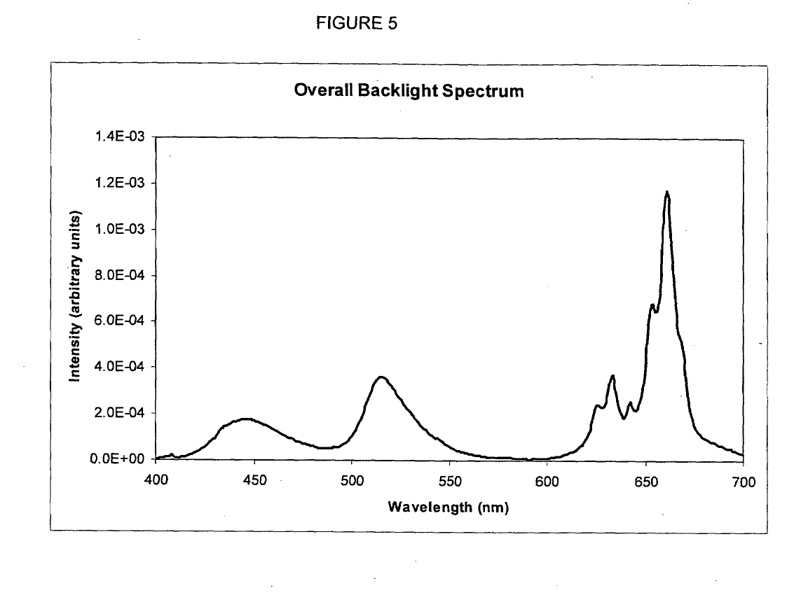

Illustrated in FIG. 5 is a blend of the spectral power distribution for a simulation of a backlight using 3.5MgO*0.5MgF₂*GeO₂: Mn⁴⁺ as the red phosphor, BaMgAl₁₀O₁₇: Eu²⁺, Mn²⁺ as the green phosphor and Sr₅(PO₄)₃Cl: Eu²⁺ as the blue phosphor, and balanced to the color coordinates of the standard CIE illuminant D65 (x=0.3127, y=0.3291). Other color coordinates, e.g. corresponding to higher or lower color temperatures, can be achieved by adjusting the relative intensities of the emissions from the phosphors, as known in the art.

1. A diode backlight apparatus comprising:
a plurality of radiation emitting diodes, each emits radiation having a peak wavelength of about less than 430 nm, located on a back surface of a housing;
the housing having an opening;
a screen covering the opening, the screen includes a discrete pattern of phosphor coated red light emitting pixels, a second discrete pattern of phosphor coated blue light emitting pixels, and a third discrete pattern of phosphor coated green light emitting pixels;
a radiation regulating element proximate the screen; and
a diffuser proximate the diodes.

2. The apparatus of claim 1 wherein the radiation regulating element comprises a shutter.

3. The apparatus of claim 2 wherein the shutter comprises a type of shutter selected from the group of mechanical shutter, digital light processor, micro-electro-mechanical system and electro-optical shutter.

4. The apparatus of claim 1 wherein the radiation regulating element comprises an actuated polarizing filter.

5. The apparatus of claim 1 wherein the diffuser comprises a refractory diffuser.

6. The apparatus of claim 1 wherein the red light emitting pixels, the green light emitting pixels, and the blue light emitting pixels comprise a plurality of pixels and a ratio of the plurality of diodes to the plurality of pixels comprises less than about 1:1.

7. The apparatus of claim 1 further comprising a UV filter located above the screen.

8. The apparatus of claim 1 wherein the apparatus having a thickness of less than about seven (7) inches.

9. The apparatus of claim 1 wherein the diodes comprise power LEDs.

10. The apparatus of claim 1 wherein the phosphor coated pixels further include one or more pigments.

11. The apparatus of claim 1 wherein a peak wavelength of the one or more pixels of the discrete pattern of red light emitting pixels comprises between about 610 nm to about 660 nm.

12. The apparatus of claim 11 wherein red light emitting pixels comprise a material selected from oxysulfides doped with Eu³⁺, oxyfluorides doped with Mn⁴⁺, complex fluorides doped with Mn⁴⁺, nitridosilicates doped with Eu²⁺, and combinations thereof.

13. The apparatus of claim 12 wherein the material has the chemical formula of at least one of 3.5MgO*0.5MgF₂*GeO₂: Mn⁴⁺, La₂O₂S: Eu³⁺, K₂[TiF₆]: Mn⁴⁺, CaAlSiN₃: Eu²⁺, and combinations thereof.

14. The apparatus of claim 1, wherein a peak wavelength of the one or more pixels of the discrete pattern of green light emitting pixels comprises between about 500 nm to about 560 nm.

15. The apparatus of claim 14 wherein the green light emitting pixels comprise a material selected from thiogallates doped with Eu²⁺, silicates doped with Eu²⁺, sulfides doped with Cu⁺, aluminates doped with Eu²⁺, and combinations thereof.

16. The apparatus of claim 15 wherein the material comprises one selected from SrGa₂S₄: Eu²⁺, Ba₂SiO₄: Eu²⁺, ZnS: Cu⁺, SrAl₂O₄: Eu²⁺ and BaMgAl₁₀O₁₇: Eu²⁺, Mn²⁺, and combinations thereof.

17. The apparatus of claim 1 wherein a peak wavelength of the one or more pixels of the discrete pattern of blue light emitting pixels comprises between about above 440 nm to about 470 nm.

18. The apparatus of claim 17 wherein the blue light emitting pixels comprise a material selected from halophosphates doped with Eu²⁺, sulfides doped with Ag⁺, BaMgAl₁₀O₁₇: Eu²⁺, and combinations thereof.

19. The apparatus of claim 18 wherein the material comprises one selected from Sr₅(PO₄)₃Cl: Eu²⁺, ZnS: Ag⁺, and combinations thereof with or without BaMgAl₁₀O₁₇: Eu²⁺.

20. The apparatus of claim 1 wherein a transmittance of the diffuser comprises at least about 80%.

21. The apparatus of claim 1 wherein the peak wavelength comprises a wavelength in a range of 390 to 420 nm.

22. The apparatus of claim 1 wherein the screen includes a mask around the discrete pattern of red, green, and blue emitting pixels.

23. A diode backlight apparatus comprising:
a plurality of radiation emitting diodes, each diode emits radiation having a peak wavelength of about less than 430 nm, located on a back surface of a housing;
the housing having a thickness of about five (5) inches or less and an opening;
a screen covering the opening, the screen includes a discrete pattern of phosphor coated red light emitting pixels, a second discrete pattern of phosphor coated blue light emitting pixels, and a third discrete pattern of phosphor coated green light emitting pixels;
a radiation regulating element proximate the screen, and
a diffuser proximate the diodes.

24. A LED backlight apparatus comprising:
a plurality of LEDs, each LED having a peak wavelength of about less than 430 nm, located on a back surface of a housing;
the housing having an opening;
a screen covering the opening, the screen includes a discrete pattern of phosphor coated red light emitting pixels, a second discrete pattern of phosphor coated green light emitting pixels, and a third discrete pattern of phosphor coated blue light emitting pixels; and
a radiation regulating element proximate the screen.
